(19) United States
(12) Patent Application Publication
(10) Pub. No.: US 2016/0036379 A1
(43) Pub. Date: Feb. 4, 2016

(54) HYBRID SOLAR THERMAL AND PHOTOVOLTAIC SYSTEM WITH TERMAL ENERGY CATURE SUBSYSTEM

(71) Applicant: Richard Lyle SHOWN, Santa Rosa, CA (US)

(72) Inventor: Richard Lyle Shown, Santa Rosa, CA (US)

(21) Appl. No.: 14/775,652

(22) PCT Filed: Mar. 11, 2014
(86) PCT No.: PCT/US14/23785

§ 371 Date: Sep. 11, 2015

Related U.S. Application Data
(63) Continuation of application No. 13/794,538, filed on Mar. 11, 2013, now abandoned.

(51) Int. Cl. H02S 40/44; F24J 2/24; H01L 31/052

(52) U.S. Cl. CPC H02S 40/44; H01L 31/052; F24J 2/24

(57) ABSTRACT

A hybrid photovoltaic and solar thermal system for generating electrical energy and providing heated water for storage or immediate use. The system includes photovoltaic solar panels, each attached to base with an open top, a bottom, and sides. A base cover is connected to the base sides to define a fluid reservoir. A fluid inlet disposed in each side of the bases provide water to the reservoir from a water supply. A fluid outlet disposed in the sides of each base discharges heated water from the reservoirs through a discharge pipe connected to hot water storage tanks.

### BACKGROUND OF THE INVENTION

1. Technical Field

The present invention relates generally to photovoltaic solar electric power generating systems and solar thermal collectors, and more particularly to a combination photovoltaic electric energy generation and solar thermal collection system.

2. Background Art

In the known art, generally denominated 10 in FIGS. 1-2, solar panels 12 linked so as to form an array are typically fabricated in a generally planar form are disposed in a generally planar or slightly tilted configuration. An array may comprise a large number of panels mounted in supports, frames, racks, or the like, with panels 12 positioned generally in the same plane [FIG. 2] or in parallel planes, with the individual panels tilted at an optimum angle relative to the Sun's incident rays so as to maximize solar insolation, typically by positioning the panels so that the incident rays 14 of the sun are as close to perpendicular to the plane of the panels for as long a period of time as possible. Obviously, the optimal tilt varies according to the latitude in either the Northern or Southern Hemisphere in which the system is located, with the tilt angle often matching the installation's latitude.

In fixed systems the panels generally produce useful power for only a portion of the day. In consequence, tracking systems are used to adjust (either continually or in discrete steps) the tilt of the panels in relation to the sun so as to produce useful power for longer periods of the day. Unfortunately, large scale motorized tracking systems are expensive and consume substantial amounts of electrical energy themselves, thereby siphoning off a portion of the energy that would otherwise be available for productive use outside the array.

In solar thermal systems, the solution is to employ shaped reflectors (parabolic mirrors, heliostats, and so forth) so as to eliminate the need for adjusting the solar concentrators in relation to a conduction medium (typically a pipe located at the focal point). However, providing similarly designed fixed reflectors for PV panels has not been the focus of research and design efforts, principally because the panels themselves are intended to capture energy directly.

It is well known that photovoltaic solar panels decrease in efficiency as their temperatures rise. In consequence, it is customary in the solar power industry to ensure that ample air circulation and ventilation is provided behind and around the panels to facilitate air cooling. This is generally accomplished by mounting the panels on support poles embedded in ground or installed on a roof top. Thus, air is the medium generally employed to remove thermal energy from PV panels.

Water has also been employed as a coolant and the heated water reclaimed for use. FIG. 1 shows in greatly simplified schematic form the kind of assembly used for effecting heat exchange between a heat exchange fluid 16 and solar panels. Most commonly the apparatus includes either a fluid plenum or a constellation of pipe 18 in physical contact with the underside 20 of one or more panels. The circulation system is most often ganged such that the heat exchange medium flows across and under a large number of panels before being circulated out for productive use or for storage before use.

The systems known by the present inventor fail to balance optimal electrical output with optimal solar thermal heating by using fixed volumes of water for cooling only until heated to the point where the water continues to cool the panels and thereby ensure efficient electricity production while also remaining efficient for water heating; i.e., more efficient than heating the water using gas burners or electrical heating elements.

The foregoing patents reflect the current state of the art of which the present inventor is aware. Reference to, and discussion of, these patents is intended to aid in discharging Applicant's acknowledged duty of candor in disclosing information that may be relevant to the examination of claims to the present invention. However, it is respectfully submitted that none of the above-indicated patents disclose, teach, suggest, show, or otherwise render obvious, either singly or when considered in combination, the invention described and claimed herein.

### DISCLOSURE OF INVENTION

The system of the present invention is a combined or hybrid photovoltaic/solar thermal energy system that structurally and operationally integrates a medium temperature thermal energy collector with photovoltaic solar panels. In its most essential aspect, the preferred embodiments of the present invention include: (1) a water source; (2) a panel holder and heat exchanger structure integrating photovoltaic solar panels and solar thermal water system; (3) a control system for controlling the supply of water to the panel holder and heat exchanger; and (4) a plurality of highly insulated storage tanks for receiving water heated in the heat exchangers. The system may include a secondary but complementary subsystem for separating suffused gases encapsulated or trapped in solids or liquids.

The foregoing summary broadly sets out the more important features of the present invention so that the detailed description that follows may be better understood, and so that the present contributions to the art may be better appreciated. There are additional features of the invention that will be described in the detailed description of the preferred embodiments of the invention which will form the subject matter of the claims appended hereto.

Accordingly, before explaining the preferred embodiment of the disclosure in detail, it is to be understood that the disclosure is not limited in its application to the details of the construction and the arrangements set forth in the following description or illustrated in the drawings. The inventive apparatus described herein is capable of other embodiments and of being practiced and carried out in various ways.

Also, it is to be understood that the terminology and phraseology employed herein are for descriptive purposes only, and not limitation. Where specific dimensional and material specifications have been included or omitted from the specification or the claims, or both, it is to be understood that the same are not to be incorporated into the appended claims.

As such, those skilled in the art will appreciate that the conception, upon which this disclosure is based may readily be used as a basis for designing other structures, methods, and systems for carrying out the several purposes of the present invention. It is important, therefore, that the claims are regarded as including such equivalent constructions as far as they do not depart from the spirit and scope of the present invention. Rather, the fundamental aspects of the invention, along with the various features and structures that characterize the invention, are pointed out with particularity in the claims annexed to and forming a part of this disclosure. For a better understanding of the present invention, its advantages and the specific objects attained by its uses, reference should be made to the accompanying drawings and descriptive matter in which there are illustrated the preferred embodiment.

### BRIEF DESCRIPTION OF THE DRAWINGS

The invention will be better understood and objects other than those set forth above will become apparent when consideration is given to the following detailed description thereof. Such description makes reference to the annexed drawings wherein:

FIG. 1 is a highly schematic side view in elevation of a prior art photovoltaic and solar thermal combination, wherein a heat exchanger is disposed on the backside of the PV panel and a heat transfer fluid is circulated through the heat exchanger (a simple run of pipe);

FIG. 2 is a top plan view thereof;

FIG. 3 is a schematic side view in elevation of a the reflector and panel elements of the preferred embodiment of the inventive hybrid PV and solar thermal system;

FIG. 3A is a highly schematic side view in elevation of the reflector and panel elements of an alternative embodiment of the present invention;

FIG. 4 is a schematic top plan view of an array comprising an alternatively shaped panel holder and water reservoir, the assembly including panels disposed over a reservoir having a heat absorbing cover;

FIG. 5 is an upper exploded perspective view of the panel holder and water reservoir assembly of FIG. 4;

FIG. 6 is a block diagrammatic view showing a system utilizing a panel holder and solar thermal water reservoir of the kind shown in FIGS. 4-5 or variations thereon;

FIG. 7 is a cross-sectional side view in elevation of the apparatus of FIGS. 4-5;

FIG. 8A is a cross-sectional side view in elevation showing an alternative embodiment of the panel holder and water reservoir, showing the panel having a convex curvature and the reservoir cover having a concave curvature; and

FIG. 8B is a cross-sectional side view in elevation showing another embodiment with the panel and reservoir top both generally planar.

### BEST MODE FOR CARRYING OUT THE INVENTION

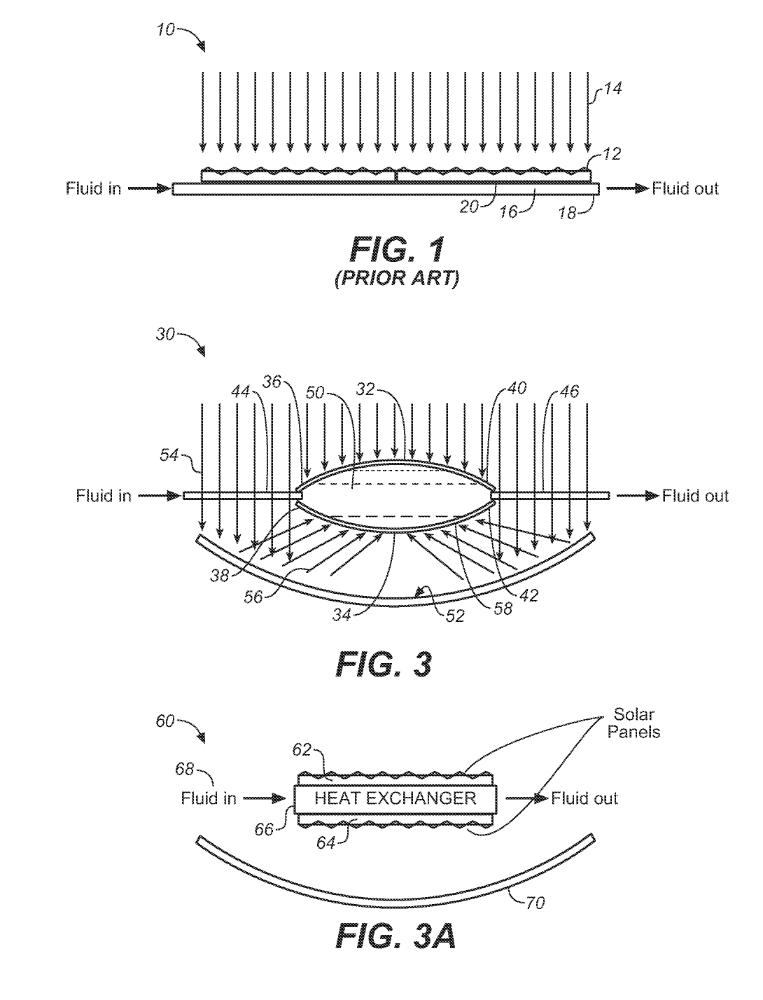

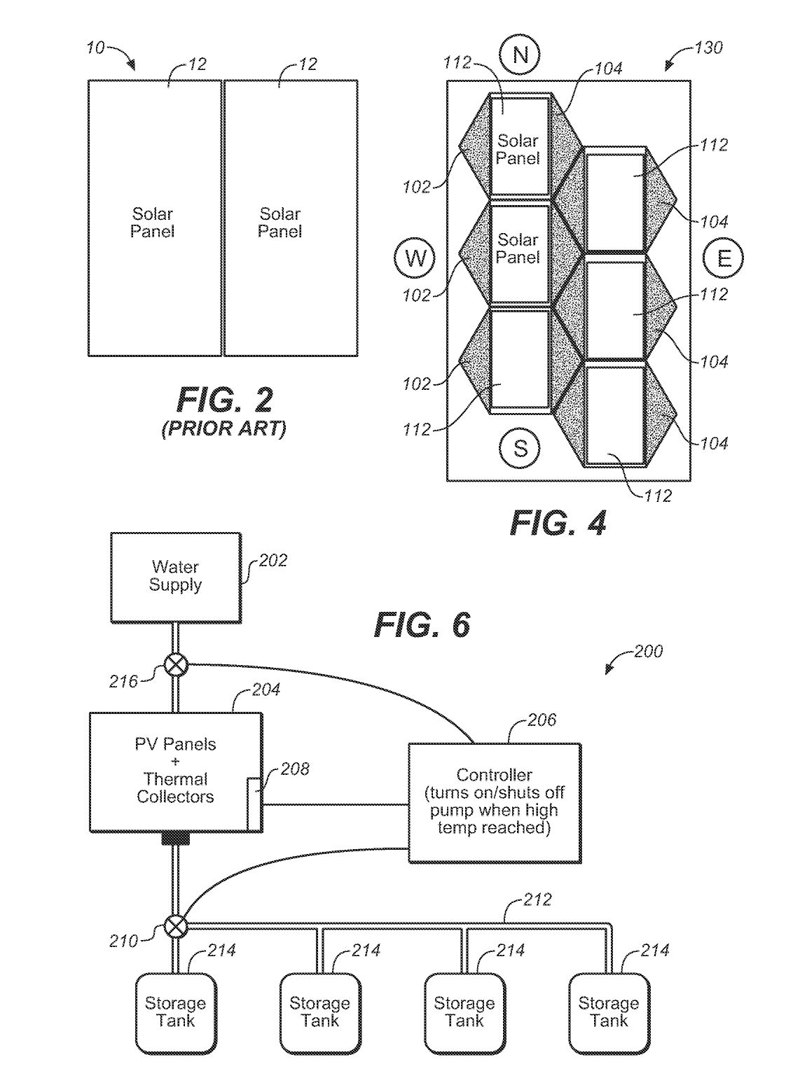

Referring to FIGS. 1 through 8B, wherein like reference numerals refer to like components in the various views, there is illustrated therein a new and improved combined or hybrid photovoltaic/solar thermal energy system, generally denominated 100 herein.

Referring first to FIG. 3, which is a highly schematic side view in elevation of a preferred embodiment of the inventive system 30, there is shown the geometric configuration of a module suitable for installation in an array. Each module includes an upper convex solar photovoltaic panel 32 spaced apart from a lower concave photovoltaic solar panel 34 having a convex configuration with a radius of curvature substantially the same as that of the upper convex panel. The generally rectangular curved panels are sealingly joined at their shorter (width) ends, 36, 38, 40, 42, and include a fluid inlet 44 at a sealed first end and a fluid outlet 46 at a sealed second end 48. The fluid inlet and fluid outlet are preferably simple pipes.

The space 50 between the upper and lower panels is filled with a heat exchange fluid, preferably water. The sides of the panels (not shown) are joined by vertically disposed and sealingly closed walls which conform with the shape defined by the spaced apart line segments of the upper and lower panels, seen here to describe a slice or section of a generally prolate spheroid (much like an American football shape).

Disposed beneath and spaced apart from the lower solar panel 34 is a reflective surface 52 that reflects incident rays 54 from the sun upwardly in reflected rays 56 to the underside 58 (which is the side with exposed cells) of the lower panel 34. Thus, not only does the upper panel 32 produce electrical power, but so too does the lower panel 34.

Further, the water introduced into the space 50 between the panels is heated by the inherently inefficient solar panels, which convert a substantial portion of their absorbed solar energy into heat, and transfer that energy to the heat exchange fluid. Convection and mixing of the fluid volume by differential heating of the panel surfaces facilitates uniform heating throughout the volume. In this approach the panel backs themselves function as the heat exchange surfaces, thereby bringing the heat exchange medium directly into contact with the panels. This is vastly more efficient than including a heat exchanger between the panels, inasmuch as the structural elements comprising the fluid container of a heat exchanger themselves be involved in the heat conduction is interposed between the panels and the fluid, and the fluid thus does not carry away as much thermal energy as the above-described system.

However, and referring now to FIG. 3A, there is shown a highly schematic cross-sectional view of an alternative configuration 60 that also advantageously accomplishes the desired electrical power and hot water production described in relation to the embodiment shown in FIG. 3. The principle of operation is essentially identical, with the exception that the upper and lower panels, 62, 64, are generally planar and are disposed above and below and in contact with a heat exchanger (a pipe or plenum) 66 through which cooling fluid 68, preferably water, is circulated. In this embodiment, the modules again include a concave reflector 70 disposed below the lower panel 64 for reflecting solar radiation upwardly and to the solar cells of the lower panel.

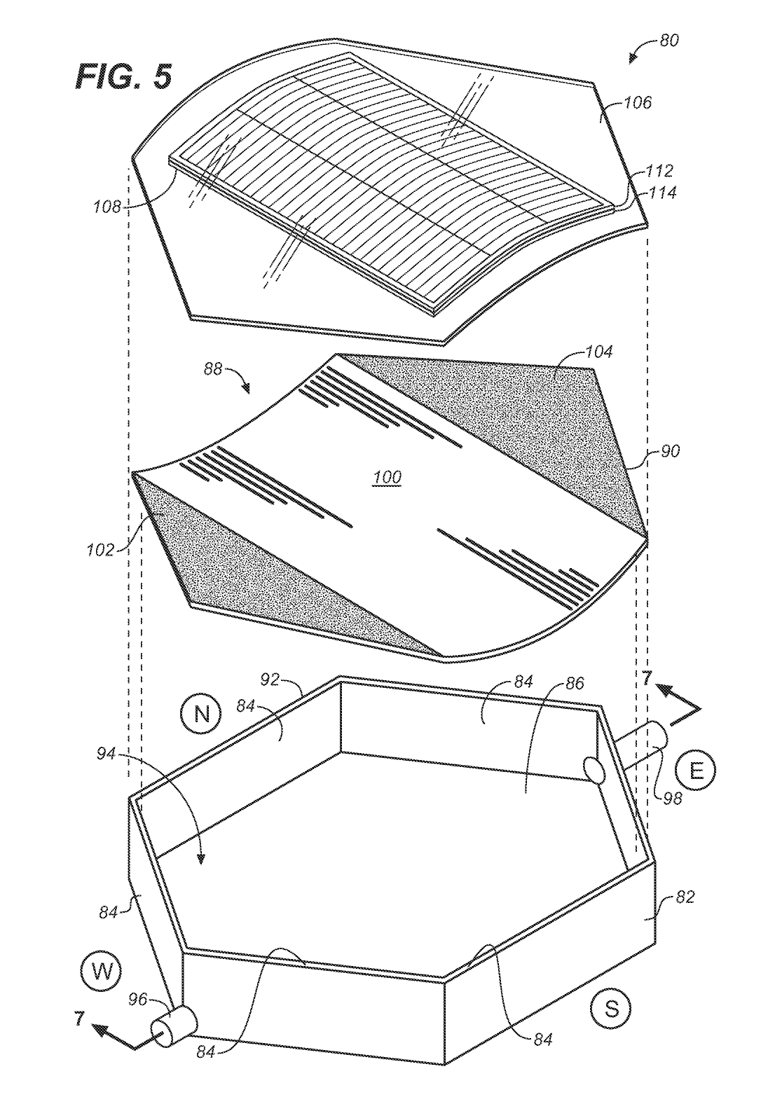

Turning now to FIGS. 5-7, there is shown yet another embodiment 80 of the inventive combined photovoltaic and solar thermal module for installation in an array. In this embodiment, the inventive system first includes a base 82 that functions as a water reservoir and as a panel support structure. The base is preferably constructed from stainless steel, for instance 18 gauge stainless steel, with a #303 alloy specification. The material selection is driven principally by the thermal and corrosion resistance properties of stainless steel. The base is preferably hexagonal, the sides 84 being approximately 300 mm in height by 448 mm in length. The outside dimension from each of the equilateral sides of the hexagon to the parallel opposite side shall be approximately 925 mm. Foam insulation (not shown) in a thickness of approximately 37-38 mm covers the exterior of each side. Each side also includes a fiberglass-cloth protective coating (or a comparably protective coating, such as a fiber reinforced polymer). The bottom 86 of the base is covered with insulation of greater thickness than on the sides, preferably about 150 mm, and the exterior surface bottom side shall also include one or more layers of fiberglass or fiber reinforced polymer.

The hexagon base has a hexagonal concave base cover 88, preferably stainless steel, welded around its periphery 90 to the upper rims 92 of the base sides 84 so as to create a reservoir space 94 for containing water. The reservoir space is in fluid communication with a water supply through a fluid inlet 96 and in fluid communication with hot water storage tanks through a fluid outlet 98.

The concave base cover is curved in the east-west direction and includes a center portion 100 and a west wing 102 and east wing 104. The center portion is deeply polished stainless steel having a highly reflective mirror finish. The mirror finished center portion preferably has a width of approximately 520 mm×900 mm. The upper surfaces of the east and west wings are coated with black automotive-quality paint containing an iron oxide pigment. Alternatively, the wings may be painted with a high temperature cooking paint, such as RUST-OLEUM® fully opaque high heat enamel Bar-B-Que black paint. The curvature of the concave base cover can be adapted to the latitude of the installation, though a preferred radius of curvature is 0.707 the longest dimension from opposing vertices. [RUST-OLEUM is a registered trademark of Rust-Oleum Brands Company of Vernon Hills, Ill.]

Fittings for the inlet and outlet connectors are inert and non-reactive materials that do not induce corrosion in the system. For Northern Hemisphere installations, the outlet is preferably installed on should be mounted on the South bottom of the hexagon base and the inlet on the North top of the base, and for Southern Hemisphere installations the inlet and outlets are reversed. In the view, the inlet and outlet are shown on the east and west sides only for purposes of clarity, but it should be understood that the exact location is not limiting. The preferred configuration relates to the tilt that the modules may be provided in one or the other hemispheres so as to increase sun exposure, and the fluid inlet side would thus be located slightly above the fluid outlet so as to provide natural gravity induced drainage.

Optionally, the bottom side of the hexagon base may include integral flanges (not shown) extending outwardly from the sides 84 to provide structure through which bolts can be passed for mounting the apparatus on an elevated frame.

The apparatus next includes a convex cover 106 with curvature in an east/west direction and having a radius of curvature substantially matching that of the concave base cover. It is preferably fabricated from clear polycarbonate (or comparably durable, impact resistant, and transparent) material approximately 0.5 cm in thickness. The convex cover is shaped and sized to attach to the upper rims 92 of the base, preferably using stainless steel screws. Calking may be placed between the convex cover and the base rims so as to provide an airtight seal, though simple screw attachment is generally sufficient and facilitates easy removal for panel maintenance and repair.

Disposed in a polycarbonate pocket 108 either on top of or on the underside 110 of the convex cover are two outwardly facing back-to-back upper and lower photovoltaic solar panels 112, 114, the pocket and the panels having an east/west curvature matching that of the convex cover. Thus the solar cell side 116 of the upper panel 112 is convex and the solar cell side 118 of the lower panel is concave. Incident solar rays 120 strike both the blackened east and west wings, as well as the reflective center portion, which sends reflected radiation 122 into the solar cells of the lower panel 114.

Optionally disposed between the back-to-back upper and lower panel is a thick (1 cm) black dielectric sheet 124 to dissipate the heat generated by the panels and to inhibit electrical generation between the two panels. When the convex cover with the pocket 108 for the panels is fixed to the stainless steel hexagon base 82, the length dimension of the panels enclosed in the polycarbonate pocket shall be positioned in a north-south orientation. The interior dimensions of the pocket may be approximately 800 mm by 400 mm and the pocket is centered on or under the hexagon cover. The interior dimensions of the hexagon cover shall be approximately 900 mm from equilateral, parallel opposing side to side. This dimension may vary to accommodate to the manufacturing dimensions of the stainless steel hexagon solar collector.

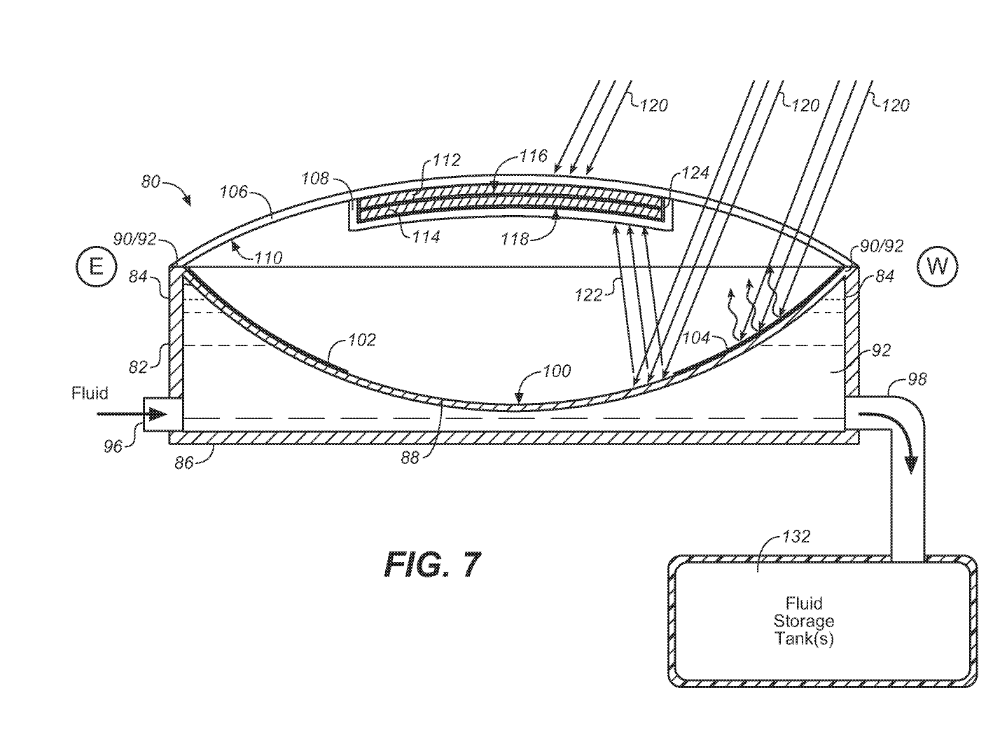

FIG. 4 shows how the assembled modules of this embodiment can be deployed in an array 130. It will be appreciated from this schematic top plan view that the hexagonal modules comprising the base, concave base cover, convex cover, and solar panels are arranged in a honeycomb-type configuration. If closely spaced, the fluid inlets and outlets may be positioned so as to create either a continuous fluid line through a plurality of modules, or each module can discharge into a pipe or pipes that converge at one or more hot water storage tanks 132 (see FIG. 7).

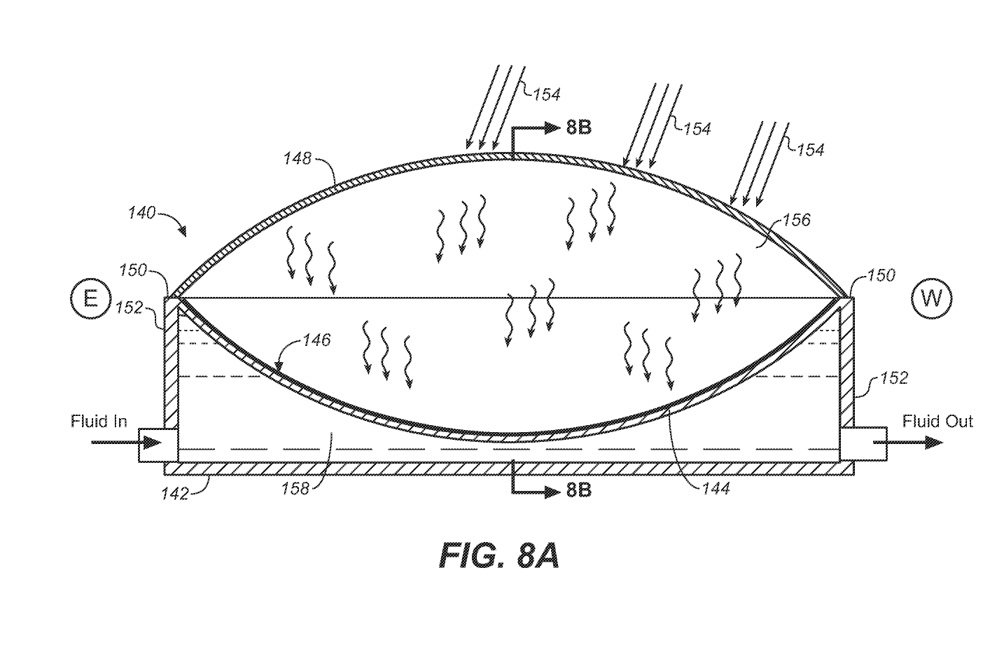

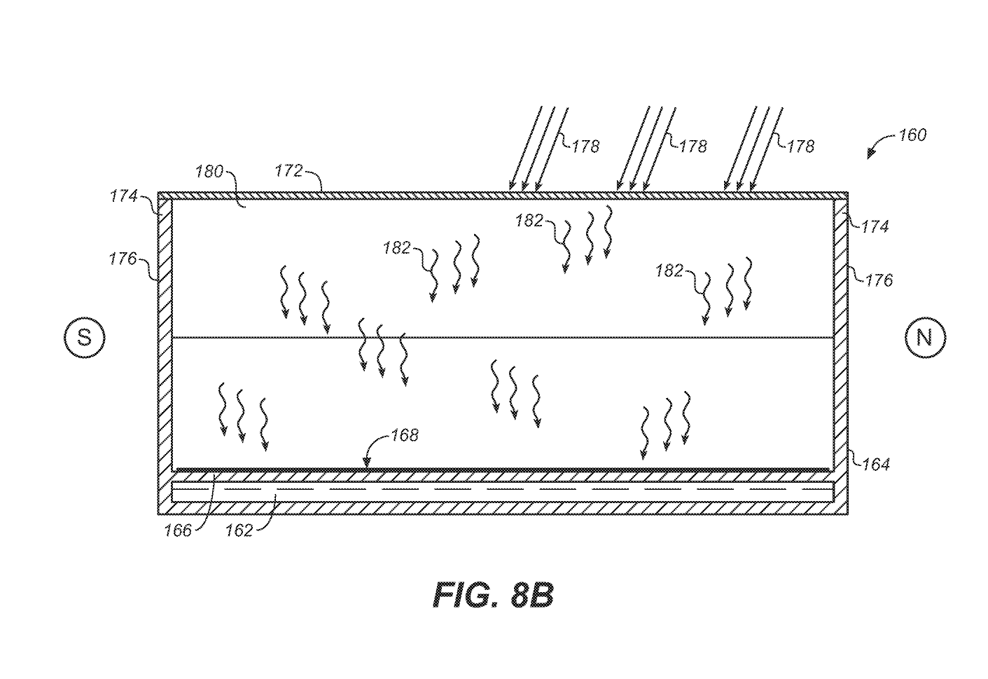

Turning next to FIG. 8A there is shown a schematic cross-sectional side view in elevation of yet another alternative configuration for the inventive hybrid photovoltaic and thermal solar energy collection system. In this embodiment 140, the elements of the base 142 and concave base cover 144 are similar to those of the embodiment shown in FIG. 5 and FIG. 7. However, the base is itself rectangular and rather than having a central reflective portion on the upper surface 146 of the concave base cover 144, the entire upper surface of the concave base cover is coated with light absorbing iron oxide paint (or functionally comparable coating). Further, a single rectangular but convex photovoltaic solar panel 148 with curvature from east to west is sealingly affixed to the upper rims 150 of the base sides 152 and functions as the module cover. The concave base cover and the convex cover each have a radius of curvature that is preferably 0.707 the width dimension of the rectangular base. In this embodiment, incident solar radiation 154 does not penetrate the module cover. Instead, solar energy absorbed by the panel and converted into heat is conducted through the air space 156 where it is absorbed, in turn, by the concave base cover upper surface 146 and further in turn, the entirety of the cover. Heat energy is thereafter transferred to the preferred heat exchange medium—water—contained within the space 158 defined by the base and concave base cover and flowing under the concave base cover.

FIG. 8B shows yet another alternative embodiment 160, this iteration moving in the direction of the more conventional systems, at least insofar as it includes a relatively small space 162 through which a heat exchange fluid is circulated and/or temporarily contained. As with the embodiment shown in FIG. 8A, the base 164, preferably rectangular, includes a rectangular sealed base cover 166 having an upper surface 168 coated with an iron oxide or functionally equivalent pigment or paint. In this embodiment, the module cover 170 is a single rectangular and substantially planar photovoltaic panel 172 affixed to the upper rims 174 of the base sides 176. Incident solar radiation 178 is partially converted into heat and is conducted through the air space 180 defined by the solar panel 172 and the base cover 166, which absorbs the thermal energy 182 and transfers it to the water.

Looking now at FIG. 6 it will be seen that in any of the foregoing embodiments of the hybrid assembly, a system 200 can be configured to provide water from a water supply 202 for single pass circulation and/or repeated re-circulation through the fluid space in one or more PV panel modules 204 (i.e., the reservoirs with the assemblies). Alternatively, it can be retained in the reservoirs and discharged by opening an electronically operated valve under the control of a signal from a controller coupled to a temperature sensor located in the fluid reservoir. The system preferably includes a simple, digital control panel for interfacing with a controller 206 that receives signals from temperature sensors 208 located in the fluid reservoirs of the structural base units. The temperature-sensors inform the controller of the fluid temperature of the water contained in each base collector. Once the temperature reaches an optimum and predetermined degree, preferably 95° C., the controller signal the discharge pump 210 to release the heated water from the reservoirs to a manifold 212 that will empty into one or more storage tanks 214. Once the heated water has been discharged, he controller signals an water supply pump 216 to open so that cool water from the water supply is provided to the modules 204.

As will be appreciated, support structure may be (and preferably is) provided to support the modules of the inventive system. The support structure is not illustrated in the views inasmuch as the supports themselves are known and well-established in the art.

Likewise, the storage tanks employed in the inventive system are well-known, and numerous kinds may be productively employed. Thus, particular tank specifications are determined for optimal system efficiency. The tanks are located proximate the support structure in sequence from east to west in proportion to a predetermined surface area of PV solar panels. While the system supplies hot water during hours when the sun is shining, the use of heated water for all residential, industrial, commercial institutional and governmental purposes occurs at almost any time of the day or night. By providing a system of insulated storage tanks, the heat energy supplied by the solar collector units can be reserved for later use at the option of the user.

Each hot water storage tank in the system is constructed of 18 gauge, #303 specification, stainless steel having a top fitted with a central 450 mm operable door, for cleaning and inspection purposes. An inlet threaded fitting (with a union coupling) shall be welded to the top of the tank. An outlet threaded fitting (with union coupling) shall be welded near the bottom of the tank.

The tanks are insulated with blown-on foam insulation with the curvature of the insulation fitting tightly to the tank sides. The thickness of the blown-on insulation shall be 7.5 cm (a second layer of insulation will be applied over the first player in order to obtain an optimum thickness of 15 cm of insulation.) A protective coating of a fiberglass cloth mat (or comparable coating) is applied, sprayed and cured to obtain durability and weatherability. This second application of a fiberglass cloth mat (sprayed and cured) to ensure durability needed for all locations may be omitted at the option of the local installer.

To facilitate shipping and installation at a variety of sites, the storage tanks should be standardized for most applications. The insulated tanks will likely be transported in conventional standard 40-foot long shipping containers. Therefore, the stainless steel tanks (inconclusive of the insulation required) cannot have dimensions exceeding the interior dimension of the shipping containers. Together with 15 cm (total of 30 cm) of foam insulation, the tanks should not exceed 2 m in diameter. This leaves 10 cm on either side of the shipped tank for easy insertion into the shipping container. The insulated tank may not exceed 10 feet in height from its bottom to the top of the clean-out manhole.

Under certain conditions gases, such as methane and certain alcohols, permeate certain solids and liquids by dissolving into the substrate past the point of saturation. A case in point is the absorption of methane by groundwater, thus rendering it unfit for human consumption. Another case in point is the decomposition of organic matter into its various components of volatile organic molecules. There are a multitude of additional commercial, industrial, institutional and governmental processes which require the separation of diffuse gases in various solids and liquids. By heating the impacted solid or liquid to a sufficiently high temperature, the volatile gases diffused in those impacted solids and/or liquids may be separated by evaporation, and then condensed and pressurized to serve various useful functions. An elevation in temperature will accelerate the evaporative process. But currently, these processes require the use of energy from fossil fuels, e.g., reverse-osmosis, and so forth.

This evaporation process can be employed for use with even more complicated soluble solids and debris in liquid/solid solutions from which entrapped gases are evaporating and being fermented (or off-gassing) from the heated solution. For example, in the case of municipal waste, i.e., sewage, more efficient, or large-scale structures may be engineered to handle the “through-put” volumes. The source of the heat energy may comprise the solar units described above. The heat energy may be transferred through tubes or pipes of corrosion-resistant material buried in a concrete base to hold the liquid/solid. In the case of farm manure, for example, the structure may be efficient heat-transfer piping encased in a shallow concrete basin with a large, heavy plastic “tent” connected to a condensing and liquefying process.

These structures must be electrically grounded to prevent ignition of the volatile gases by the buildup of static electricity. In addition, the entire system can be installed on a low-boy and transported to an affected site by motor transport. A military operation could use the units to treat drinking water in advanced locations or at bases and could include self-contained sewage treatment facilities at the advanced base.

From the foregoing, it will be seen that in its most essential aspect, the inventive system is a hybrid photovoltaic and solar thermal system for generating electrical energy and providing heated water for storage or immediate use. The system includes photovoltaic solar panels, each attached to base with an open top, a bottom, and sides. A base cover is connected to the base sides to define a fluid reservoir. A fluid inlet disposed in each side of the bases provide water to the reservoir from a water supply. A fluid outlet disposed in the sides of each base discharges heated water from the reservoirs through a discharge pipe connected to hot water storage tanks. Electrically controlled valves on the inlet and outlets are under the control of a controller coupled to temperature sensors in the reservoirs, such that water is released from the reservoirs and replenished to the reservoirs only after water contained in the reservoirs reaches a predetermined temperature.

The above disclosure is sufficient to enable one of ordinary skill in the art to practice the invention, and provides the best mode of practicing the invention presently contemplated by the inventor. While there is provided herein a full and complete disclosure of the preferred embodiments of this invention, it is not desired to limit the invention to the exact construction, dimensional relationships, and operation shown and described. Various modifications, alternative constructions, changes and equivalents will readily occur to those skilled in the art and may be employed, as suitable, without departing from the true spirit and scope of the invention. Such changes might involve alternative materials, components, structural arrangements, sizes, shapes, forms, functions, operational features or the like.

Therefore, the above description and illustrations should not be construed as limiting the scope of the invention, which is defined by the appended claims.

1. A system for use in a system for generating electrical energy and providing heated water for storage or immediate use, comprising:
at least one photovoltaic solar panel;
at least one photovoltaic solar panel holder for holding at least one each of said at least one photovoltaic panels, said solar panel holder including a base having an open top, a bottom, and sides with upper rims;
a base cover connected to said base sides of each of said solar panel holders so as to define a reservoir in each of said solar panel holders for containing fluid between said bottom and said cover;
a water supply;
a fluid inlet disposed in a side of said base and in fluid communication with said water supply through a water supply pipe, such that water can be introduced into said reservoirs;
a fluid outlet disposed in a side of each of said bases for discharging fluid from said reservoirs through a discharge pipe;
an electrically controlled inlet valve disposed on said fluid inlets or said water supply pipe for controlling input water to said reservoirs;
an electrically controlled outlet valve disposed on said fluid outlets or said discharge pipe for controlling the discharge of water from said reservoirs;
a temperature sensor disposed in each of said reservoirs for sensing the temperature of water contained in said reservoirs; and
a controller electrically connected to said temperature sensors and each of said inlet and outlet valves, wherein when water in a particular reservoir reaches a predetermined optimally high temperature during daylight hours, said controller opens said outlet valve to discharge hot water from that particular reservoir and then opens an inlet valve to provide a supply of fresh water from said water supply to the reservoir or reservoirs from which water has been discharged.

2. The system of claim 1, further including at least one insulated water storage tank in fluid communication with said discharge pipe for receiving and storing hot water discharged from said reservoir.

3. The system of claim 1, wherein said base cover is sealingly affixed to said base so as to form a watertight seal.

4. The system of claim 1, where said base cover is concave.

5. The system of claim 4, wherein said base cover has an upper surface with at least a portion coated with opaque black paint.

6. The system of claim 5, wherein said base cover is fabricated from stainless steel and further includes a reflective portion on said upper surface.

7. The system of claim 6, wherein said reflective portion of said base cover is disposed between two opaque black coated portions.

8. The system of claim 7, further including:
a transparent convex cover attached to said upper rims of said base sides, and
a first upwardly facing photovoltaic panel and a second downwardly facing photovoltaic panel, the latter for receiving reflected solar radiation from said reflective portion of said base cover.

9. The system of claim 8, wherein said photovoltaic panels are disposed in a transparent pocket affixed to said transparent convex cover.

10. The system of claim 9, wherein said convex cover is fabricated from polycarbonate.

11. The system of claim 1, wherein said base cover is substantially planar.

12. The system of claim 1, wherein said at least one photovoltaic solar panel covers the entirety of the area defined by said base open top.

13. The system of claim 12, wherein said at least one photovoltaic solar panel is generally planar.

14. The system of claim 13, wherein said base cover is generally planar.

15. The system of claim 12, wherein said at least one photovoltaic solar panel is convex and said base cover is concave.

16. The system of claim 1, wherein said further including a convex cover connected to said upper rims of said base sides.

17. The system of claim 16, wherein said convex cover is transparent to allow the passage of solar radiation to said base cover.

18. The system of claim 1, further including a plurality of insulated water storage tanks in fluid communication with one or more of said discharge pipes for receiving and storing hot water discharged from said reservoir.

19. The system of claim 18, wherein said controller is electrically connected to one or more storage tank discharge valves for controlling the release of hot water from said storage tanks.
